(19) United States
(12) Patent Application Publication
(10) Pub. No.: US 2021/0219434 A1
(43) Pub. Date: Jul. 15, 2021

(54) METHOD FOR PREPARING ELECTROMAGNETIC SHIELDING FILM

(71) Applicant: SHENZHEN KNQ TECHNOLOGY CO., LTD., Shenzhen (CN)

(72) Inventors: Longfeng SONG, Shenzhen (CN); Kegui LI, Shenzhen (CN); Yao CHEN, Shenzhen (CN)

(73) Assignee: SHENZHEN KNQ TECHNOLOGY CO., LTD.

(21) Appl. No.: 17/197,104

(22) Filed: Mar. 10, 2021

Related U.S. Application Data
(63) Continuation of application No. PCT/CN2019/083183, filed on Apr. 18, 2019.

(30) Foreign Application Priority Data
Sep. 10, 2018 (CN) 201811049491.3

(51) Int. Cl. H05K 3/28; H05K 1/02; H05K 9/00

(52) U.S. Cl. CPC H05K 3/281; H05K 2201/0195; H05K 9/0096; H05K 1/0218

(57) ABSTRACT

The present disclosure provides a method for preparing an electromagnetic shielding film. The method comprises the following steps: providing a carrier film layer, and preparing an insulating layer on the carrier film layer; performing conductive treatment on the insulating layer by means of vacuum plating; placing an insulating layer matrix having undergone conductive treatment in an alkaline electrolyte, and performing electroplating sedimentation on the surface of the matrix at least three times using an alkaline solution precipitation method so as to prepare a metal shielding layer; placing the metal shielding layer in a micro-etching solution, and performing surface micro-etching to obtain a micro-etched layer; and performing acid solution sedimentation treatment at least once to prepare a foamed metal layer, and sequentially preparing a conductive adhesive layer and a protective film layer on the surface of the foamed metal layer, thereby obtaining an electromagnetic shielding film.

### TECHNICAL FIELD

The present disclosure belongs to the technical field of electromagnetic shielding films, and particularly relates to a method for preparing an electromagnetic shielding film.

### BACKGROUND

As the modern electronic industry is rapidly developed, a large amount of electric appliances and electronic equipment are widely applied to industrial production and people's daily life, thereby promoting the development of industrial technologies, improving people's life and increasing the people's living quality. However, the electric appliances and electronic equipment can radiate a large amount of electromagnetic waves during the use, the electromagnetic waves cause hazards not to be neglected on normal and safe operation of electronic appliances and human's living environment. With the sharp increase of quantities of various wireless communication systems and high-frequency devices, an electromagnetic interference phenomenon and electromagnetic pollution problems are increasingly outstanding. Electromagnetic energy in human living environment is increased year by year, and it is difficultly avoided that the electromagnetic environment is deteriorated in the 21^{st} century.

In the existing flexible printed circuit (FPC) products, to selectively cover the protective circuits, eliminate the influence of exogenous interference electromagnetic signals and expose welding spots, shielding film layers are all arranged on the surfaces of PFC. For example, invention patent CN101176388 discloses a shielding film, the shielding film comprising: an isolation film; a cover film arranged on one surface of the isolation film; various functional layers are formed using a printing manner. The shielding film is used to protect the circuits of the flexible printed circuit meanwhile shielding interference electromagnetic signals. However, due to restriction of the materials and process performance of the shielding film layer, the shielding effect of such the shielding film in a high-frequency circuit board is not optimistic.

### SUMMARY

The object of the present disclosure is to provide a method for preparing an electromagnetic shielding film, aiming at solving the poor shielding effectiveness and conductivity problems of the existing electromagnetic shielding film on the high-frequency circuit board.

In order to realize the above object, the technical solution adopted by the present disclosure is as follows.

One aspect of the present disclosure provides a method for preparing an electromagnetic shielding film, comprising the following steps:

providing a carrier film layer, and preparing an insulating layer on the carrier film layer;

performing conductive treatment on the insulating layer by means of vacuum plating;

placing an insulating layer matrix having undergone conductive treatment in an alkaline electrolyte, and performing electroplating sedimentation on the surface of the matrix at least three times using an alkaline solution precipitation method so as to prepare a metal shielding layer;

placing the metal shielding layer treated with the alkaline solution into a micro-etching solution, and performing surface micro-etching to obtain a micro-etched layer;

placing the micro-etched metal shielding layer in an acidic electrolyte, and performing acid solution sedimentation treatment at least once to prepare a foamed metal layer; and

sequentially preparing a conductive adhesive layer and a protective film layer on the surface of the foamed metal layer, thereby obtaining the electromagnetic shielding film

According to the method for preparing the electromagnetic shielding film provided by the present disclosure, the insulating layer matrix is subjected to conductive treatment and then placed in the alkaline electrolyte, and sedimentation is performed on the surface of the conductive layer many times using an alkaline solution sedimentation method so as to prepare the metal shielding layer; and the metal shielding layer is further placed in an acidic electrolyte, the surface of the metal shielding layer is treated using an acid solution sedimentation method to obtain a foamed metal layer. The resulting electromagnetic shielding film has a three-dimensional and porous structure having a rough surface. Firstly, the conductive adhesive layer is further deposited on the basis of the foamed metal layer, the material of the conductive adhesive layer can be permeated into convex points of the foamed metal layer to form a double-layer occlusion structure, which avoids generation of non-conductive gaps in the foamed metal layer and the conductive adhesive layer and effectively prevents electromagnetic leakage, thereby improving the electromagnetic shielding performance. Secondly, in the step of preparing the micro-etched layer, a porous structure is prepared in the metal shielding layer, which effectively reduces a phenomenon that bubbles occur during the use of the electromagnetic shielding film and enhances the use reliability of the shielding film. Thirdly, acid solution sedimentation is performed after at least three times of alkaline solution sedimentation, which can improve the thickness of the deposited metal layer, further enhance the conductive property and improve the electromagnetic shielding effect. The resulting electromagnetic shielding film has a shielding effectiveness as high as 70 dB.

### DESCRIPTION OF THE EMBODIMENTS

To make the to-be-to solved technical problems, technical solution and beneficial effects of the present disclosure more clear and understandable, the present disclosure will be further described in detail in combination with examples. It should be understood that specific embodiments described here are only for explaining the present disclosure, but are not limited to define the present disclosure.

In the description of the present disclosure, it should be understood that the term “first” and “second” are only for describing the purpose but cannot be understood as indicating or implying relative importance or implicitly indicating the quantity of the technical features. Accordingly, the features defining “first” and “second” can clearly indicate or implicitly including one or more of these features. In the description of the present disclosure, “plurality” means two or more than two, unless definitely and specifically defined.

The example of the present disclosure provides a method for preparing an electromagnetic shielding film, comprising the following steps:

S01, providing a carrier film layer, and preparing an insulating layer on the carrier film layer;

S02, performing conductive treatment on the insulating layer by means of vacuum plating;

S03, placing an insulating layer matrix having undergone conductive treatment in an alkaline electrolyte, and performing electroplating sedimentation on the surface of the matrix at least three times using an alkaline solution precipitation method so as to prepare a metal shielding layer;

S04, placing the metal shielding layer in a micro-etching solution, and performing surface micro-etching to obtain a micro-etched layer;

S05, placing the micro-etched metal shielding layer in an acidic electrolyte, performing acid solution sedimentation treatment at least once to prepare a foamed metal layer; and

S06, sequentially preparing a conductive adhesive layer and a protective film layer on the surface of the foamed metal layer, thereby obtaining an electromagnetic shielding film.

According to the method for preparing the electromagnetic shielding film provided by the present disclosure, the insulating layer is subjected to conductive treatment and then placed in the alkaline electrolyte, and many sedimentations are performed on the surface of the conductive layer using the alkaline solution sedimentation method so as to obtain the metal shielding layer; and the metal shielding layer is placed in the micro-etching solution, and surface micro-etching is performed to obtain a micro-etched layer; the metal shielding layer is further placed in the acidic electrolyte, and the metal shielding layer is treated using acidic liquid sedimentation method to obtain the foamed metal layer. The resulting electromagnetic shielding film has a three-dimensional porous rough surface structure. Firstly, the conductive adhesive layer is further deposited on the basis of the foamed metal layer, the material of the conductive adhesive layer can be permeated into convex points of the foamed metal layer to form a double-layer occlusion structure, which avoids generation of non-conductive gaps in the foamed metal layer and the conductive adhesive layer and effectively prevents electromagnetic leakage, thereby improving the performance of the electromagnetic shielding layer. Secondly, in the step of preparing the micro-etched layer, a porous structure is prepared in the metal shielding layer, thereby effectively reducing the phenomenon of bubbles occurring during the use of the electromagnetic shielding film and enhancing the use reliability of the shielding film. Thirdly, acid solution sedimentation is performed after at least three time of alkaline solution sedimentation, which can improve the thickness of the deposited metal layer, further enhance the conductive property and improve the electromagnetic shielding effect. The resulting electromagnetic shielding film has a shielding effect as high as 70 dB.

Specifically, in the above step S01, the carrier film layer can select the conventional carrier film layer in the art. Specifically, the carrier film layer is formed by coating a silicon oil release agent or a silicon-free release agent on the surface of a base film and further UV curing. Where, the base film can be selected from one of a polyimide film, a polyphenylene sulfide (PPS) film and a polyester film, and the thickness of the base film is 15 μm˜20 μm, the thickness of the silicon oil release agent or silicon-free release agent is 0.1 μm˜30 μm The curing method is as follows: the base film coated with the silicon oil release agent or silicon-free release agent is subjected to UV curing and then undergoes bake curing at 50˜80° C. to form a carrier film layer containing a release layer

Further, the insulating layer is deposited on the carrier film layer, which is achieved preferably using a solution processing method, that is to say, the insulating layer is made using the solution processing method. The solution processing method is preferred but is not limited to a coating method The material of the insulating layer is selected from modified epoxy resin adhesive or high-temperature resistant ink. Specifically, the modified epoxy resin adhesive or high-temperature resistant ink having a thickness of 1 μm˜50 μm is coated on the carrier film layer and subjected to bake curing at 50° C.˜180° C. to obtain the insulating layer.

In the above step S02, conductive treatment is performed on the insulating layer by means of vacuum plating to make a preparation for obtaining a metal plating layer on the insulating layer. The obtained conductive layer obtained via conductive treatment is at least one of silver, copper, gold, aluminum, tungsten, zinc, nickel, iron, platinum and titanium metals, or alloys formed by at least two of the above listed metal single substances.

Preferably, process parameters for performing conductive treatment on the insulating layer by means of vacuum plating are as follows: working vacuum plating pressure: 0.1˜100 Pa, speed: 0.5˜50 m/min; resistance value: ≤200Ω, working pressure: 500˜1000V, working current: 50˜500 A, and argon amount: 10˜500 SCCM.

In the above step S03, the matrix having undergone conductive treatment is placed in the alkaline electrolyte, and performing electroplating and copper precipitation on the surface of the matrix having undergone conductive treatment at least three times using an alkaline copper precipitation method so as to prepare the metal shielding layer. Through at least three times of electroplating and copper precipitation, relatively proper thickness can be achieved, and requirements that the shielding effect can be more than 60 dB and a surface resistance is less than 50 mΩ can be accomplished. If copper precipitation is performed once or twice, the surface of the shielding film semi-finished product cannot be completely covered, and a relatively intact metal layer cannot be obtained.

Preferably, the process parameters for obtaining the metal shielding layer by alkaline solution sedimentation are as follows:

The insulating layer matrix pretreated via vacuum plating is placed in the alkaline electrolyte having a metal ion concentration of 1˜30g/L and pH of 7˜13, and performing alkaline solution sedimentation treatment under the current of 1˜50 A Specifically, under the current of 1˜50 A, the relatively good deposition film layer can be obtained. If the current is too high, the film surface will be burnt, and if the current is too low, deposition of metal on the film surface will be affected. The proper metal ion concentration is beneficial to obtaining of a uniform and dense film layer If the concentration of the metal ions is too low, the deposition of metal will be affected, and if the concentration of the metal ions is too high, the thickness of the metal layer cannot be controlled to result in uneven thickness. Under the condition of pH 7˜13, the metal ions in the solution has the strongest activity, which is favorable to deposition of the film layer.

In the example of the present disclosure, the metal shielding layer subjected to alkaline solution sedimentation treatment typically has extremely high brightness, which is not favorable to bonding of the conductive adhesive layers and defines the thickness of the conductive adhesive layers and further limits the conductivity and shielding property of the electromagnetic shielding layer film.

In view of this, in the above step S04 of the example of the present disclosure, the metal shielding layer matrix subjected to alkaline solution sedimentation treatment is placed in the micro-etching solution, and performing surface micro-etching. Micro-etching treatment is performed on the surface plating layer through an acidic first-grade electrolyte containing a micro-etching agent so that the porous structure occurs on its surface, which is favorable to discharge of interlayer bubbles when the conductive adhesive layer is prepared on the surface of the subsequently obtained foamed metal layer, thereby improving an adhesion force between layers.

Preferably, in the step of performing micro-etching treatment on the surface metal plating layer using micro-etching solution, the micro-etching solution includes an inorganic acid and a micro-etching agent, and the micro-etching agent is used as a main micro-etching functional component, the inorganic acid is used as a catalyst, so that the micro-etching agent exerts a better property and the micro-etching degree is effectively controlled. Where, the inorganic acid includes but is not limited to nitric acid, hydrochloric acid and sulfuric acid.

Further preferably, in the micro-etching solution, the mass concentration of the inorganic acid is 150˜300 g/L, and the mass concentration of the micro-etching agent is 100˜200 g/L If the mass concentration of the micro-etching agent is too low, the micro-etching difficulty will be increased, and even micro-etching cannot be achieved; if the mass concentration of the micro-etching agent is too high, excessive corrosion will be easily caused, too large holes will be caused or a rugged surface will be formed, so that the plating layer cannot be used as the metal layer of the electromagnetic shielding film. If the concentration of organic acid is too high, it will affect the chemical balance in the reaction process of the micro-etching agent, the micro-etching effect will be affected, and even other chemical reactions can be triggered except micro-etching action. Only under the conditions of a proper inorganic acid and micro-etching agent, the micro-etching is performed on the surface of the surface metal plating layer, and the uniform porous structure is formed.

Under the condition of the above first-grade electrolyte, the treatment conditions for performing micro-etching treatment using the first-grade electrolyte are as follows: current intensity is 10˜50 A, temperature is 15˜35 , and the surface roughness Ra of the obtained micro-etched layer is 5˜20. The metal shielding layer subjected to micro-etching treatment has a porous structure having a pore size of less than 0.1 mm.

After that, in the above step S05, after micro-etching treatment, the metal shielding layer is placed in the acidic electrolyte, and the foamed metal layer is prepared on the surface of the metal shielding layer using an acid solution sedimentation method. The foamed metal layer is directly made into the metal shielding layer, which has a rough surface and is loose and porous. Then when the conductive adhesive layer is arranged, the adhesive can be permeated therein, so that the metal layer more tightly binds to the conductive adhesive layer.

Preferably, the metal shielding layer is placed in the acidic electrolyte, acid solution sedimentation treatment is performed at least once, the metal shielding layer having a bright surface is pretreated by controlling the proper ion concentration and current. Preferably, in the acidic electrolyte, the concentration of metal ions is 10˜150 g/L, the concentration of hydrogen ions is 100˜500 g/L, and the current is 10˜200 A. The relatively rough foamed metal layer can be obtained by using electrolysis conditions such as strong acidity and large current.

Further preferably, the matrix subjected to acid solution sedimentation treatment is placed in the acidic electrolyte for precipitation again, so that The surface of the obtained metal layer is doped with a part of zinc and nickel ions, thereby reducing its surface activity and preventing properties from being affected due to oxidization of the surface. Here, it is noted that the precipitation performed at this moment is only for surface ion doping of the foamed metal layer but not forming a zinc nickel alloy layer, so as to avoid that the uniformity of the foamed metal layer is affected to lead to reduction in conductivity of the product. To control the doping of zinc and nickel ions and meanwhile control the doping concentrations, preferably, in the acidic electrolyte, the concentration of zinc ions is 1˜30 g/L, the concentration of nickel ions is 0.1˜50 g/L, and pH is 0˜6. Meanwhile, sedimentation treatment is performed under the current of 1˜50 A. Since the foamed metal layer is loose and porous, it is extremely easily oxidized during the preparation of the semi-finished product to cause facts that the surface resistance is enlarged and a bonding force is reduced, so as to affect the production of the subsequent conductive adhesive layer and reduction in conductivity of the finished product. Treatment of the foamed metal layer in this manner can reduce the activity of the surface so that the foamed metal layer does not generate oxidative reaction with air.

Accordingly, the electromagnetic shielding film binds to the foamed metal layer on one surface of the metal shielding layer, the metal shielding layer and the foamed metal layer are fit to achieve close bonding. The distribution of the metal shielding layer is extremely compact, which can realize excellent shielding effect and conductive effect On this basis, the foamed metal layer having a loose surface is formed, the foamed metal layer tightly binds to the metal shielding layer so that the conductive adhesive layer arranged on the surface of the foamed metal layer can be permeated therein, so as to enhance the bondability. In addition, the metal shielding layer tightly binds to the metal foamed layer, which can further enhance the shielding and conductivity of the metal layer. Besides, the conductive adhesive layer of the shielding film provided by the present disclosure contains metal conductive particles which can effectively achieve good conductivity to meet the development requirement on high-speed high-frequency electronic products.

In the above step S06, the conductive adhesive layer is prepared on the surface of the foamed metal layer by preferably using a solution processing method, specifically, the solution processing method includes but is not limited to scraper type coating, scraping stick type coating and reverse stick type coating. To improve the conductive effect of the conductive adhesive layer, preferably, the conductive adhesive layer is made of a mixed conductive material formed by compounding the modified epoxy resin and the metal conductive particles, the modified epoxy resin is the thermosetting epoxy resin. The epoxy resin itself cannot conduct electricity, the metal conductive particles are mixed in the resin through doping of metal conductive particles to serve as a conductive matrix to construct a conductive network, so that the connection between the ground point and the metal layer is accomplished, and it is avoided that conductivity is reduced due to the obstruction of the adhesive layer, thereby improving the conductivity.

Preferably, the total weight of the mixed conductive material is based on 100%, and the weight percentage of the metal conductive particles is 0.1%˜50%. If the weight percentage of the metal conductive particles is too high, the conductive materials are too dense to occupy each other's spaces and even fill touch points, so they cannot take a good conductive effect.

Further preferably, the metal conductive particle can select at least one of silver, copper, gold, aluminum, tungsten, zinc, nickel, iron, platinum and titanium metals. As one embodiment, the metal conductive particle selects at least one of silver, copper, gold, aluminum, tungsten, zinc, nickel, iron, platinum and titanium metal single substance powders. As another embodiment, the metal conductive particle is selected from alloys formed by at least two of silver, copper, gold, aluminum, tungsten, zinc, nickel, iron, platinum and titanium metals. As yet another embodiment, the metal conductive particle is a metal conductive particle having a core-shell structure, wherein the core-shell material of the metal conductive particle having a core-shell structure is selected from at least one of silver, copper, gold, aluminum, tungsten, zinc, nickel, iron, platinum and titanium metals; the inner core material of the metal conductive particle having the core-shell structure is selected from at least one of silver, copper, gold, aluminum, tungsten, zinc, nickel, iron, platinum and titanium metals, or the core material is selected from glass beads and ceramics, such as a complex of one or more of silver coated copper, silver coated nickel, silver coated iron, silver coated glass beads and silver coated ceramics. Where, the shape of the metal powder is not clearly defined, including but not limited to a spherical shape, a columnar shape, a conical shape and an irregular prismatic shape.

Preferably, a method for preparing the modified epoxy resin is as follows:

providing epoxy resin and carboxyl nitrile rubber, dissolving and mixing the epoxy resin and the carboxyl nitrile rubber to obtain a mixture, and heating the mixture for grafting reaction to obtain a flexible epoxy resin; and after cooling, adding a latent curing agent to prepare thermosetting modified epoxy resin.

Where, the epoxy resin can select bisphenol A type, bisphenol F type, phenolic type and/or ring type epoxy resin, and the epoxy equivalent is 120˜1000 g/eq, preferably 190˜500 g/eq. The toughened resin can select thermoplastic resins such as nitrile rubber, butadiene styrene rubber, butyl rubber, natural rubber, acrylate rubber, ABS and polyimide, preferably carboxyl nitrile rubber. The latent curing agent can select imidazoles, anhydrides, aromatic amines, dicyandiamine and complexes thereof

The thickness of the conducive adhesive layer described in the example of the present disclosure is 1 μm˜200 μm.

In the example of the present disclosure, the protective film is prepared on the conductive adhesive layer to obtain the electromagnetic shielding film. Cold pressing bonding and hot bonding are adopted for the protective film layer, and the protective film layer can be a polyester film, a polyester release film and a silica gel protective film, but is not limited to thereto, and its thickness is between 15 μm and 200 μm.

Next, description will be made in combination with specific examples.

### Example 1

A method for preparing an electromagnetic shielding film comprises the following steps:

S11, providing a base film having a thickness of 15 μm˜20 μm, and evenly coating a silicon oil release agent or a silicon-free release agent of 0.1 μm˜30 μm on the surface of the base film, UV curing, and then performing bake curing at 50° C.˜180° C. to form a carrier film containing a release layer; and evenly coating a modified epoxy resin or high temperature resistant ink having a thickness of 1 μm˜50 μm on the carrier film layer, and performing bake curing at 50V˜180° C. to form an insulating layer;

S12, performing conductive treatment on the insulating layer by means of vacuum plating;

S13, placing a matrix having undergone conductive treatment in an alkaline electrolyte, performing electroplating sedimentation on the surface of the conductive layer at least three times using an alkaline solution sedimentation method to obtain a semi-finished product metal layer;

S14, placing the metal shielding layer subjected to alkaline solution treatment in a micro-etching solution, and performing micro-etching treatment to obtain a metal shielding layer having a porous structure;

S15, placing the micro-etched metal shielding layer in an acidic electrolyte, and performing acidic sedimentation treatment on the surface of the metal shielding layer at least once using an acid copper precipitation method to obtain a foamed metal layer; and

S16, mixing metal conductive particles having weight percentage of 0.1%˜50% into a thermosetting epoxy resin adhesive to prepare a conductive adhesive material, and coating the conductive adhesive layer on the surface of the foamed metal layer in turn;

fitting the protective film layer on the surface of the conductive adhesive layer by cold pressure bonding or hot bonding to obtain an electromagnetic shielding film.

The electromagnetic shielding film prepared in example 1 of the invention has a shielding effectiveness being as high as 70 dB, can meet the bending service life of more than 100000 times, and has a resistance value of less than 1Ω.

The above description is only a preferred embodiment of the present disclosure, and is not intended to limit the present disclosure. Any amendments, equivalent substitutions, improvements and the like made within the spirit and principle of the present disclosure are all included in the protective scope of the present disclosure.

What is claimed is:

1. A method for preparing an electromagnetic shielding film, comprising the following steps:
providing a carrier film layer, and preparing an insulating layer on the carrier film layer;
performing conductive treatment on the insulating layer by means of vacuum plating;
placing an insulating layer matrix having undergone conductive treatment in an alkaline electrolyte, and performing electroplating sedimentation on the surface of the matrix at least three times using an alkaline solution precipitation method so as to prepare a metal shielding layer;
placing the metal shielding layer in a micro-etching solution, and performing surface micro-etching to obtain a micro-etched layer;
placing the micro-etched metal shielding layer in an acidic electrolyte, performing acid solution sedimentation treatment at least once to prepare a foamed metal layer, and
sequentially preparing a conductive adhesive layer and a protective film layer on the surface of the foamed metal layer, thereby obtaining an electromagnetic shielding film.

2. The method for preparing the electromagnetic shielding film according to claim 1, wherein placing an insulating layer matrix having undergone conductive treatment in an alkaline electrolyte, and performing electroplating sedimentation on the surface of the matrix at least three times using an alkaline solution precipitation method so as to prepare a metal shielding layer comprises:
placing the insulating layer matrix pretreated via vacuum plating in an alkaline electrolyte having metal ion concentration of 1˜30 g/L and pH of 7˜13 and performing alkaline solution sedimentation treatment under the current of 1˜50 A.

3. The method for preparing the electromagnetic shielding film according to claim 2, wherein a method for placing the metal shielding layer in a micro-etching solution, and performing surface micro-etching is as follows: after sedimentation treatment with the alkaline electrolyte, placing the metal shielding layer in an electrolyte having an inorganic acid concentration of 150˜300 g/L and micro-etching agent concentration of 100˜200 g/L, and performing surface micro-etching under the current intensity of 10˜50 A to obtain the micro-etched layer.

4. The method for preparing the electromagnetic shielding film according to claim 2, wherein placing the micro-etched metal shielding layer in an acidic electrolyte, and performing acid solution sedimentation treatment at least once to prepare a foamed metal layer comprises:
placing the micro-etched metal shielding layer in an acidic electrolyte having metal ion concentration of 10˜150 g/L and hydrogen ion concentration of 100˜500 g/L, and performing acid solution sedimentation treatment under the current of 10˜200 A.

5. The method for preparing the electromagnetic shielding film according to claim 3, wherein placing the micro-etched metal shielding layer in an acidic electrolyte, performing acid solution sedimentation treatment at least once to prepare a foamed metal layer further comprises:
placing the metal shielding layer matrix subjected to acid solution sedimentation treatment at least once in a third acidic electrolyte having zinc ion concentration of 1˜30 g/L, nickel ion concentration of 0.1˜50 g/L and pH of 0˜6, and performing sedimentation treatment under the current of 1˜50 A.

6. The method for preparing the electromagnetic shielding film according to claim 1, wherein the conductive adhesive layer is made of a mixed conductive material formed by compounding a modified epoxy resin and metal conductive particles, and the modified epoxy resin is a thermosetting epoxy resin.

7. The method for preparing the electromagnetic shielding film according to claim 5, wherein a method for preparing the modified epoxy resin is as follows:
providing an epoxy resin and a toughened resin, dissolving and mixing the epoxy resin and the toughened resin to obtain a mixture, heating the mixture for grafting reaction to obtain a flexible epoxy resin; after cooling, adding a latent curing agent to prepare the thermosetting modified epoxy resin.

8. The method for preparing the electromagnetic shielding film according to claim 5, wherein a conductive layer obtained by conductive treatment is at least one of silver, copper, gold, aluminum, tungsten, zinc, nickel, iron, platinum and titanium metals, or alloys formed by at least two of the above listed metal single substances.

9. The method for preparing the electromagnetic shielding film according to claim 5, wherein based on the total weight of the mixed conductive material being 100%, the weight percentage of the metal conductive particles is 0.1%˜50%

10. The method for preparing the electromagnetic shielding film according to claim 1, wherein process parameters for performing conductive treatment on the insulating layer by means of vacuum plating are as follows:
working vacuum plating pressure: 0.1˜100 Pa, speed: 0.5˜50 m/min; resistance value: 200Ω, working pressure: 500˜1000V, working current: 50˜500 A, and argon amount: 10˜500 SCCM.

11. The method for preparing the electromagnetic shielding film according to claim 2, wherein process parameters for performing conductive treatment on the insulating layer by means of vacuum plating are as follows:
working vacuum plating pressure: 0.1˜100 Pa, speed: 0.5˜50 m/min; resistance value: 200Ω, working pressure: 500˜1000V, working current: 50˜500 A, and argon amount: 10˜500 SCCM.

12. The method for preparing the electromagnetic shielding film according to claim 3, wherein process parameters for performing conductive treatment on the insulating layer by means of vacuum plating are as follows:
working vacuum plating pressure: 0.1˜100 Pa, speed: 0.5˜50 m/min; resistance value: 200Ω, working pressure: 500˜1000V, working current: 50˜500 A, and argon amount: 10˜500 SCCM.

13. The method for preparing the electromagnetic shielding film according to claim 4, wherein process parameters for performing conductive treatment on the insulating layer by means of vacuum plating are as follows:
working vacuum plating pressure: 0.1˜100 Pa, speed: 0.5˜50 m/min; resistance value: 200Ω, working pressure: 500˜1000V, working current: 50˜500 A, and argon amount: 10˜500 SCCM.
